(19) United States
(12) Patent Application Publication
(10) Pub. No.: US 2024/0027710 A1
(43) Pub. Date: Jan. 25, 2024

(54) EMBEDDED PHOTONICS INTEGRATED CIRCUIT IN GLASS CORE OF SUBSTRATE

(71) Applicant: Intel Corporation, Santa Clara, CA (US)

(72) Inventors: Xiaoqian Li, Chandler, AZ (US); Brandon Christian Marin, Gilbert, AZ (US); Srinivas V. Pietambaram, Chandler, AZ (US)

(73) Assignee: Intel Corporation, Santa Clara, CA (US)

(21) Appl. No.: 17/868,557

(22) Filed: Jul. 19, 2022

(51) Int. Cl. G02B 6/42

(52) U.S. Cl. CPC G02B 6/4278; G02B 6/4206

(57) ABSTRACT

In one embodiment, an integrated circuit package includes a package substrate comprising a glass core layer, an optical path at least partially in the glass core layer, and a photonics integrated circuit (PIC) at least partially embedded in the glass core layer and in optical connection with the optical path. The optical path may include a waveguide in the glass core layer and/or a microlens. The integrated circuit package may also include an electronic integrated circuit (EIC) in electrical connection with the PIC, and a processor in electrical connection with the EIC.

### BACKGROUND

Off-package input/output (I/O) bandwidth has been steadily increasing, and integrated circuit packaging and I/O technologies need to scale to meet this bandwidth demand. As a result, package pin counts and I/O data rates also continue to increase. However, the reach of electrical I/O circuits (i.e., the length of electrical PCB traces or cables) have reduced with the increased data rates. Additionally, I/O energy efficiency improvement has drastically slowed, which has resulted in a quickly approaching I/O power wall for high-performance packages. Photonics integrated circuits have shown potential benefits for both power efficiency and bandwidth improvement.

### BRIEF DESCRIPTION OF THE DRAWINGS

FIGS. 1A-1C illustrate examples of current integrated circuit packages.

FIGS. 2-4 and 5A-5B illustrate example integrated circuit packages with PICs embedded in a glass core in accordance with embodiments herein.

FIG. 6 illustrates an example manufacturing process for an integrated circuit package with an embedded PIC in accordance with embodiments herein.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a cross-sectional side view of an integrated circuit device assembly that may include embodiments disclosed herein.

FIG. 10 is a block diagram of an example electrical device that may include a microelectronic assembly, in accordance with any of the embodiments disclosed herein.

### DETAILED DESCRIPTION

In certain instances, package substrates may include permanent glass cores to prevent warpage/shrinkage when manufacturing the package. Embodiments herein include an embedded PIC within a glass core of a package substrate, with portions of the glass core being used as a connection between the PIC and a fiber array unit (FAU). The placement of the PIC within the glass core can provide one or more advantages over traditional EIC/PIC placements on top of or inside a traditional organic package substrate. For example, some embodiments may provide better optical coupling schematics, which can help both yield and system architecture compatibility. Embedding the PIC in the glass core can also provide lower overall z-height in certain instances and can enable the use of a pluggable FAU rather than a traditional pigtail FAU that needs v-grooves to align the fibers. For instance, while a PIC may be embedded in package substrate, it may need to be at least two build-up layers above the traditional, non-glass substrate core to ensure proper operation.

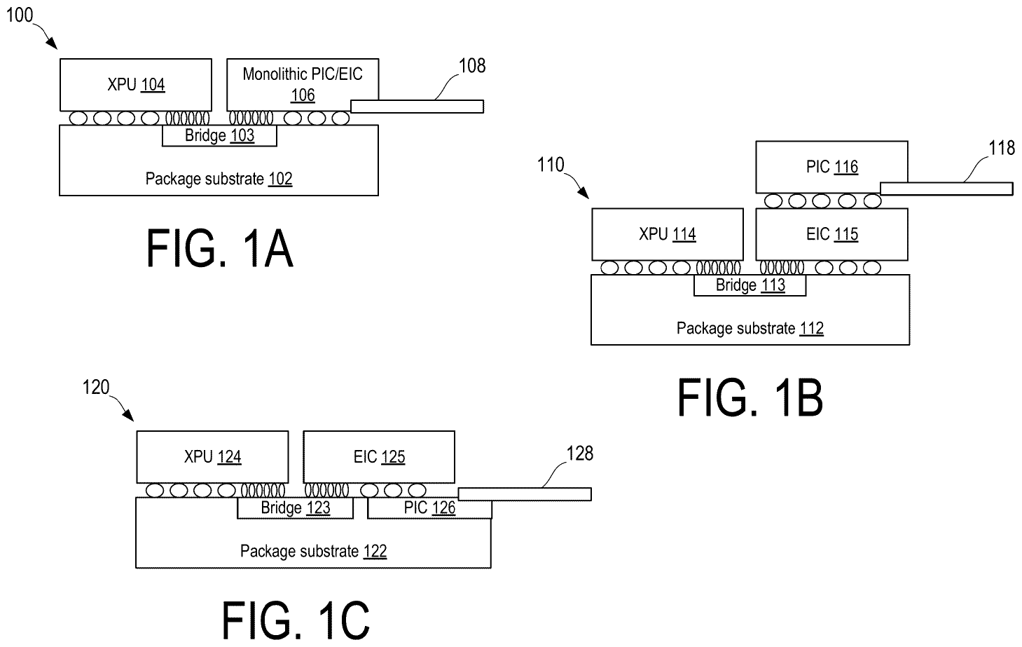

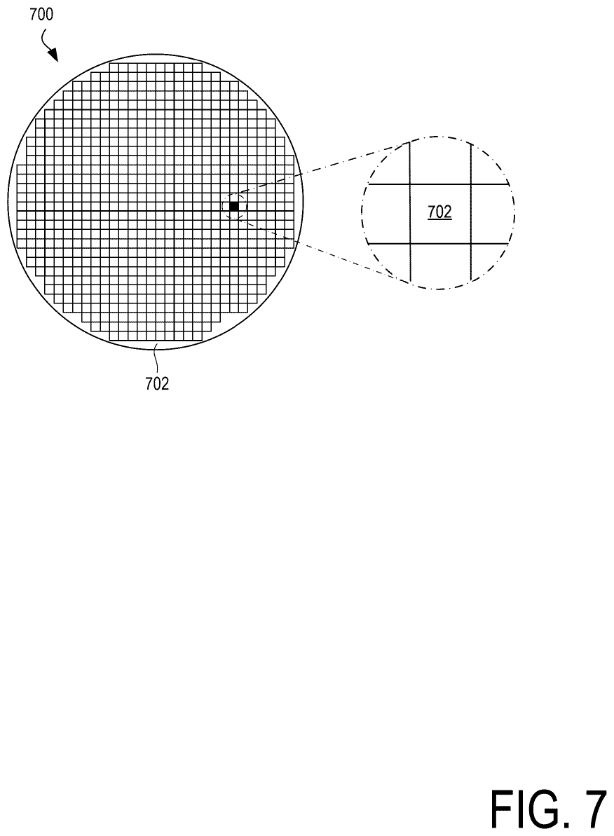

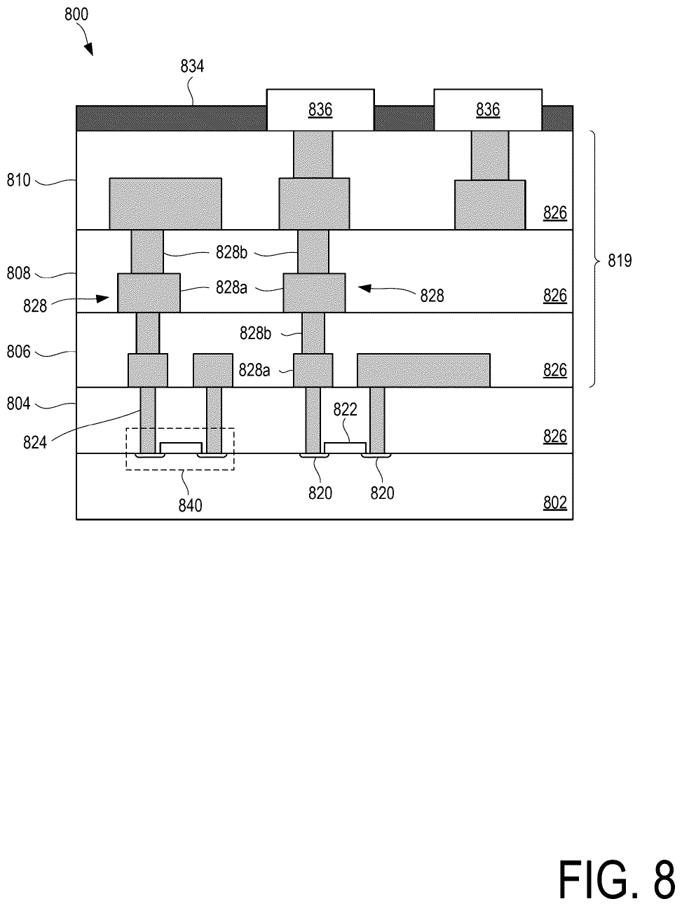

FIGS. 1A-1C illustrate examples of current integrated circuit packages 100, 110, 120. In each example shown, the package includes a package substrate (e.g., 102, 112, 122) with embedded bridge circuitry (e.g., 103, 113, 123) that interconnects processing circuitry (XPU) with a photonics integrated circuit (PIC) and an electronic integrated circuit (EIC). The bridge circuitry may be, e.g., an Intel® embedded multi-die interconnect bridge (EMIR). Any of the XPU, PIC, and EIC can be manufactured from a wafer, similar to the dies 702 of FIG. 7, and the XPU may be an integrated circuit device similar to the integrated circuit device 800 of FIG. 8. The package substrate in each example may provide interconnections between a main circuitry board (e.g., a mother board or main board) and the XPU and/or PIC/EIC.

The example shown in FIG. 1A includes a monolithic PIC/EIC die 106 that is interconnected with an XPU 104 via bridge circuitry 103 in the package substrate 102. The example shown in FIG. 1B includes a PIC die 116 on top of an EIC die 115, with the EIC die 115 being interconnected with the XPU 114 via the bridge circuitry 113 in the package substrate 112. The example shown in FIG. 1C includes a PIC die 126 embedded into the package substrate 122. The PIC die 126 is connected to an EIC die 125 on top of the package substrate 122 and is interconnected with the XPU 124 via bridge circuitry 123. As used herein, a PIC die may also be referred to as a PIC, and an EIC die may also be referred to as an EIC.

The PIC in each example may include circuitry to receive optical signals from a source (e.g., the fiber 108, 118, 128), convert the optical signals to electrical signals, and provide the electrical signals to other circuitry (e.g., to the EIC and/or the XPU). Likewise, the PIC includes circuitry to receive electrical signals (e.g., from the EIC and/or the XPU), generate optical signals based on the electrical signals, and provide the optical signals to the fiber. The PIC may include one or more lasers or other light sources, detectors, amplitude and/or phase modulators, filters, splitters, amplifiers, interferometers, microring resonators, gratings, squeezed or other quantum light sources, etc. The PIC circuitry may perform other functions beyond converting optical signals to electrical signals or vice versa, e.g., matrix multiplication, quantum logic gates, optical compute gates, etc. The EIC may include circuitry to control and/or drive the circuitry within the PIC and/or other electrical circuitry for processing the signals from the PIC. For instance, the EIC may include components such as, for example, transimpedance amplifiers (TIA), serializer/deserializer (SERDES) circuits, driver circuits, etc. The optical signals may be received from an array of fiber, e.g., a fiber pigtail connection, that is coupled to the PIC, e.g., via v-groove connections.

The XPU in each example may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units.

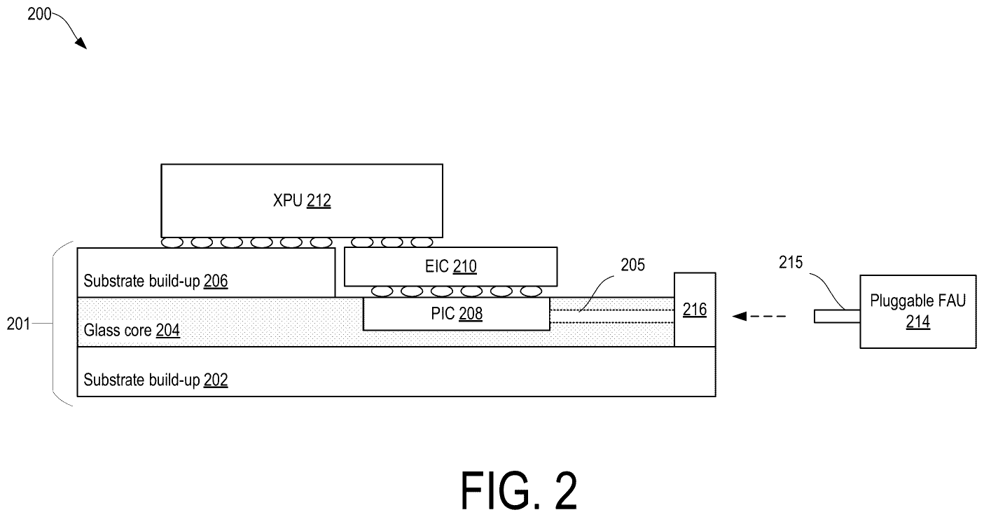

FIG. 2 illustrates an example integrated circuit package 200 with a PIC 208 embedded in a glass core 204 in accordance with embodiments herein. In the example shown, a package substrate 201 includes a glass core 204 with substrate build-up layers 202, 206 above and below the glass core 204. In some embodiments, the build-up layers 202, 206 may include redistribution layers for the substrate 201. The package 200 includes a PIC 208 embedded in the glass core 204, with an EIC 210 on the glass core 204 and in electrical connection with the embedded PIC 208. The package 200 also includes an XPU 212 that is on the substrate 201 and in electrical connection with the EIC 210. As shown, the EIC 210 is embedded within the substrate 201 and the XPU 212 is above the EIC 210.

The glass core 204 includes a waveguide 205 that directs light through the glass core 204, between the PIC 208 and an optical connection, such as a fiber optic cable. The waveguide 205 may be a laser-written waveguide in some embodiments. Other embodiments may use a pre-glass coupler with an embedded waveguide, while still other embodiments may use fiber arrays. In the example shown, there is a pluggable fiber array unit (FAU) 214 that includes an array of fiber optic cables to send/receive signals to/from the PIC 208 using the waveguide 205 inside the glass core 204. When the FAU 214 is connected to the package 200, light may be transmitted between the PIC 208 and the male portion 215 of the FAU 214 via the waveguide 205. The pluggable FAU 214 may be configured to plug into the glass core 204, or a female connector/receptacle (e.g., 216) attached to the glass core 204, without the need for v-grooves as with traditional optical connections. For instance, the pluggable FAU 214 may include one or more male portions 215 that insert into openings in the glass core 204 or into a connector (e.g., 216) coupled to the glass core 204.

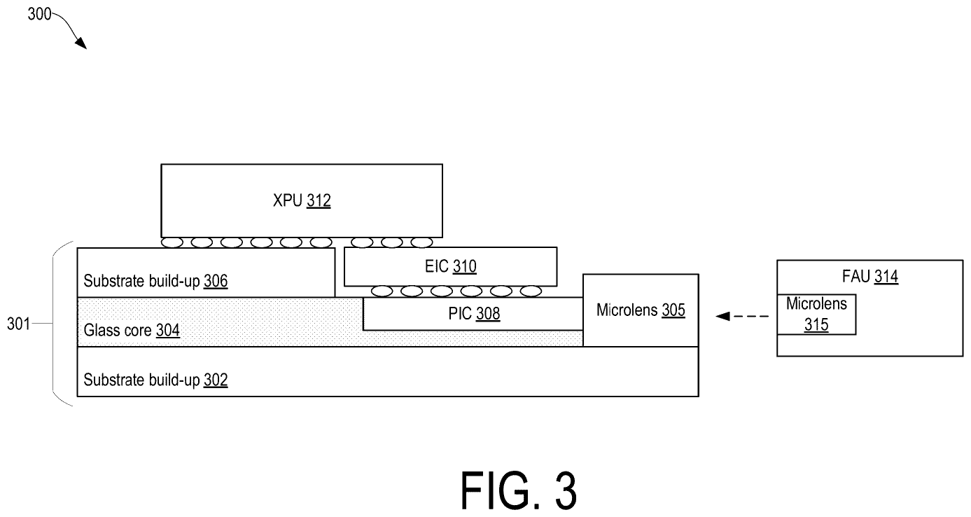

FIG. 3 illustrates another example integrated circuit package 300 with a PIC embedded in a glass core in accordance with embodiments herein. The example package 300 includes a package substrate 301 that includes a glass core 304 with substrate build-up layers 302, 306 above and below the glass core 304. In some embodiments, the build-up layers 302, 306 may include redistribution layers for the substrate 301. The package 300 includes a PIC 308 embedded in the glass core 304, with an EIC 310 on the glass core 304 and in electrical connection with the embedded PIC 308. The package 300 also includes an XPU 312 that is on the substrate 301 and in electrical connection with the EIC 310. As shown, the EIC 310 is embedded within the substrate 301 and the XPU 312 is above the EIC 310.

The example package 300 is similar to the package 200 of FIG. 2; however, it includes a microlens 305 attached to the glass core to direct light from the PIC 308 and the FAU 314. In the example shown, the microlens 305 is attached to and optically coupled with an edge of the PIC 308. The microlens 305 may be coupled to the PIC 308 using an optical epoxy, for example. Other embodiments may include a waveguide within the glass core 304 that optically couples the PIC 308 and the microlens 305. The microlens 305 may act to expand a beam size from the PIC 308, e.g., to a beam size of 50-100 um. The FAU 314 may include a microlens 315 that receives the light from the microlens 305.

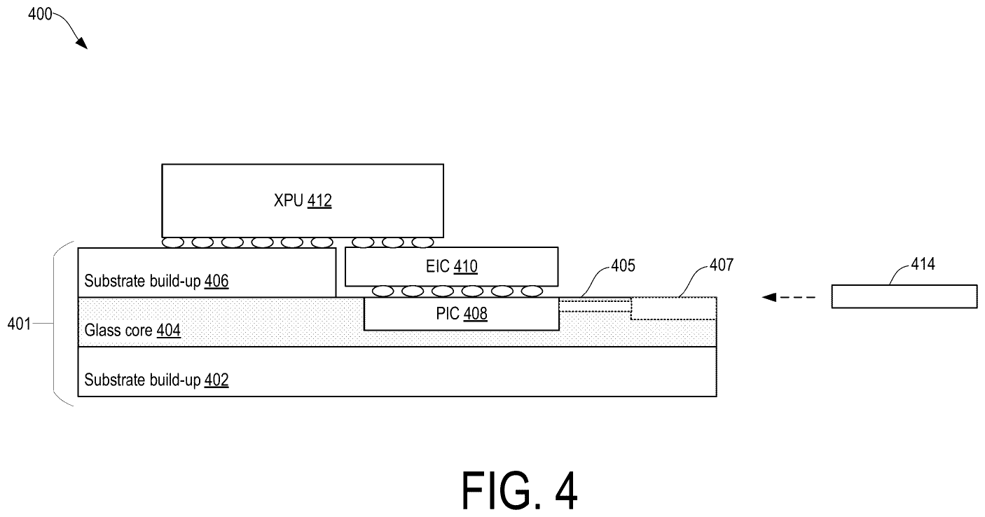

FIG. 4 illustrates yet another example integrated circuit package 400 with a PIC embedded in a glass core in accordance with embodiments herein. The example package 400 includes a package substrate 401 that includes a glass core 404 with substrate build-up layers 402, 406 above and below the glass core 404. In some embodiments, the build-up layers 402, 406 may include redistribution layers for the substrate 401. The package 400 includes a PIC 408 embedded in the glass core 404, with an EIC 410 on the glass core 404 and in electrical connection with the embedded PIC 408. The package 400 also includes an XPU 412 that is on the substrate 401 and in electrical connection with the EIC 410. As shown, the EIC 410 is embedded within the substrate 401 and the XPU 412 is above the EIC 410. The example package 400 also includes a waveguide 405 in the glass core 404, similar to the example package 200 of FIG. 2. However, the example package 400 includes v-grooves 407 at an end of the glass core to allow for connections to one or more fiber optic cables 414.

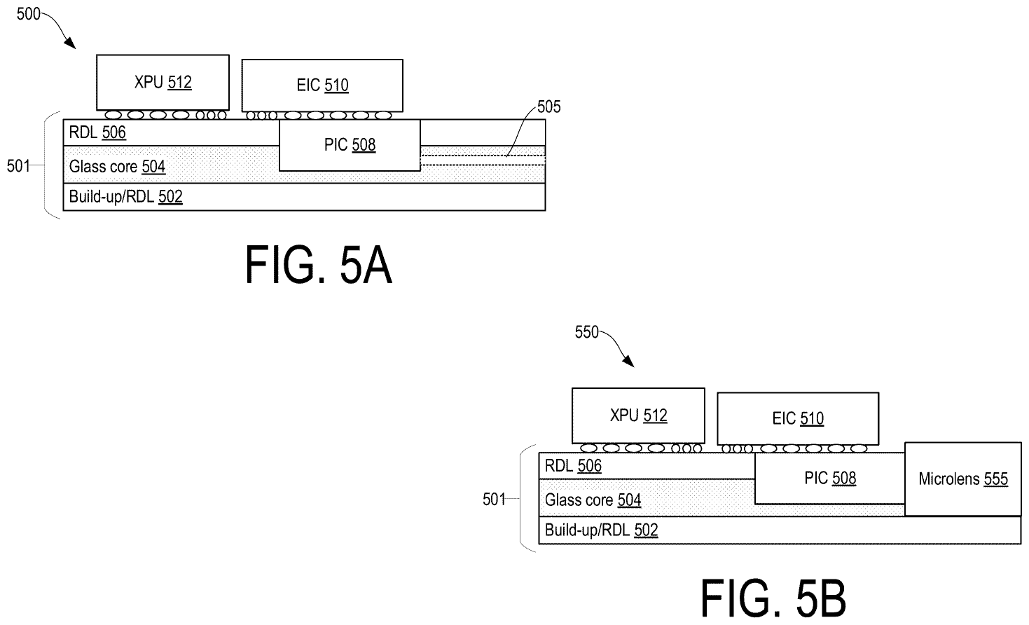

FIGS. 5A-5B illustrate further example integrated circuit packages 500, 550 having a PIC embedded in a glass core in accordance with embodiments herein. In the examples shown, the packages include a package substrate 501 that includes a glass core 504 with one or more build-up layers 502 below the glass core 504, and one or more redistribution layers 506 above the glass core 504. The package 500 also includes a PIC 508 embedded in the glass core 504, with an EIC 510 and XPU 512 on the substrate 501. The EIC 510 is in electrical connection with the PIC 508 as shown, and the redistribution layers 506 provide fine pitch electrical connections between the EIC 510 and the XPU 512. In other embodiments, bridge circuitry similar to the bridge circuitries 103, 113, 123 may be used to interconnect the EIC 510 and the XPU 512 in build up layers above the glass core 504. In the example shown in FIG. 5A, the glass core 504 includes a waveguide 505 that is similar to or the same as the waveguide 205 of FIG. 2, while the example shown in FIG. 5B includes a microlens 555 that is similar to or the same as the microlens 305 of FIG. 3. In some embodiments, there may also be a waveguide within the glass core that optically couples the PIC and the microlens shown in FIG. 5B.

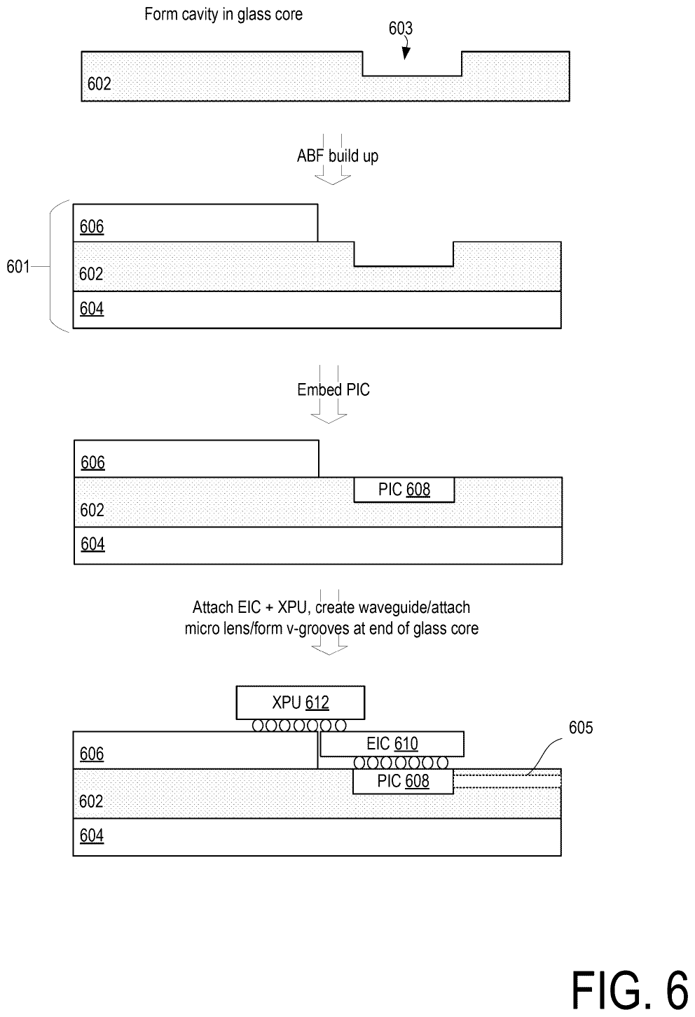

FIG. 6 illustrates an example manufacturing process 600 for an integrated circuit package with an embedded PIC (e.g., packages 200, 300, or 400) in accordance with embodiments herein. The example process shown may include additional, fewer, or different operations than those shown or described below. In some embodiments, one or more of the operations shown in FIG. 6 include multiple operations, sub-operations, etc. The illustrations of FIG. 6 may thus represent different stages in the manufacturing process.

The example process begins with forming a cavity 603 in a glass core 602. Then, the package substrate 601 is built up with build-up layers 604, 606 above and/or below the glass core 602. During this operation, though not shown, one or more vias (e.g., through silicon vias (TSVs) and/or through glass vias (TGVs)) may be formed in the substrate 601. For instance, vias may be formed to provide electrical connections between a die (e.g., an XPU) on top of the substrate and a circuit board below the substrate 601, or vias may be formed to provide electrical connections between the cavity 603 and a circuit board below the substrate 601.

A PIC 608 is then embedded in the cavity 603 of the glass core 602, and then an EIC 610 and XPU 612 are attached (e.g., as shown). Before or after embedding of the PIC 608 and/or attachment of the EIC 610 or XPU 612, an optical connection between the PIC 608 and fiber optic cables may be formed in the glass core 602. For instance, in some embodiments (and as shown in FIG. 6), a waveguide 605 may be formed in the glass core (e.g., by a laser writing process). The waveguide 605 may be laser written into the glass core after embedding the PIC in certain instances, which may allow for better optical alignment between the optical elements of the PIC and the waveguide 605.

In other embodiments, a microlens may be attached or formed adjacent the PIC 608, e.g., to provide a microlens optical connection between the PIC 608 and fiber optic cables. In some embodiments, a connection may be made in or near the glass core 602 to provide connectivity with a pluggable fiber array unit (FAU), while in other embodiments, v-grooves may be formed at the end of the glass core 602 to provide a connection with a pigtail-type FAU.

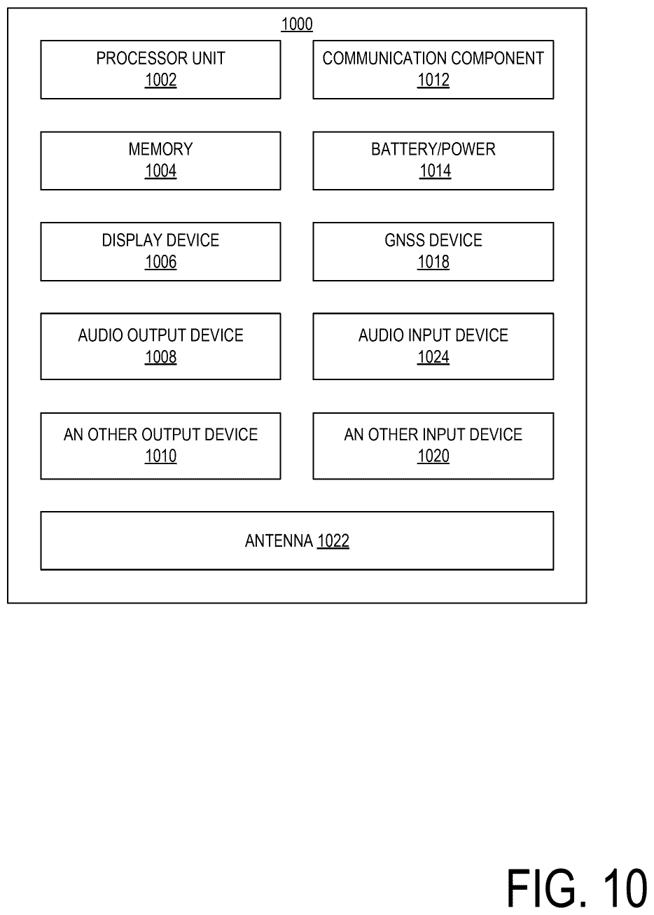

FIG. 7 is a top view of a wafer 700 and dies 702 that may be implemented in or along with any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array.

FIG. 8 is a cross-sectional side view of an integrated circuit device 800 that may be included in any of the embodiments disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board or a package substrate, e.g., 112). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

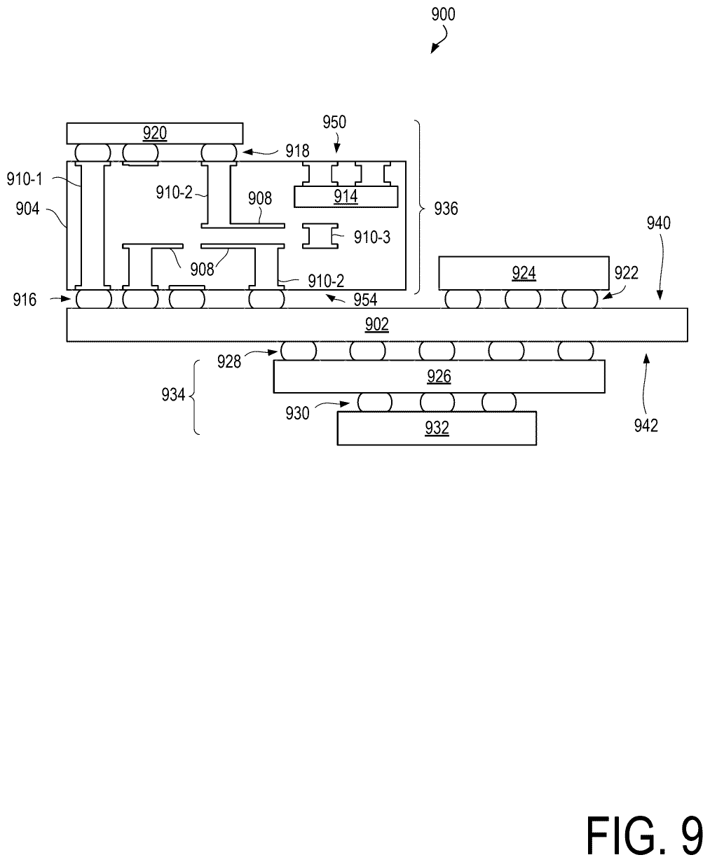

FIG. 9 is a cross-sectional side view of an integrated circuit device assembly 900 that may include any of the embodiments disclosed herein. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board.

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable ones of the components of the electrical device 1000 may include one or more of assemblies 100, integrated circuit devices 800, or integrated circuit dies 702 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit device comprising: a glass core layer; one or more build-up layers on the glass core layer; a photonics integrated circuit (PIC) at least partially within a cavity of the glass core layer; an electronic integrated circuit (EIC) in electrical connection with the PIC; and an optical path between the PIC and an end of the integrated circuit device.

Example 2 includes the subject matter of Example 1, wherein the optical path includes a waveguide formed in the glass core layer.

Example 3 includes the subject matter of Example 1 or 2, further comprising a connector to couple with a pluggable fiber array unit (FAU) and direct light from the FAU to the optical path.

Example 4 includes the subject matter of Example 1 or 2, further comprising v-grooves in the glass core to couple with optical fibers of a fiber array unit (FAU) and direct light from the optical fibers to the optical path.

Example 5 includes the subject matter of any one of Examples 1-4, wherein the optical path includes a microlens.

Example 6 includes the subject matter of any one of Examples 1-5, wherein the EIC is at least partially embedded in the one or more build-up layers.

Example 7 includes the subject matter of any one of Examples 1-5, wherein the EIC is on the build-up layers.

Example 8 includes the subject matter of any one of Examples 1-7, further comprising a processor in electrical connection with the EIC.

Example 9 includes the subject matter of Example 8, wherein the one or more build-up layers include at least one redistribution layer to electrically connect the processor and the EIC.

Example 10 is an integrated circuit package comprising: a package substrate comprising a glass core layer; an optical path at least partially in the glass core layer; a photonics integrated circuit (PIC) at least partially embedded in the glass core layer and in optical connection with the optical path; an electronic integrated circuit (EIC) in electrical connection with the PIC; and a processor in electrical connection with the EIC.

Example 11 includes the subject matter of Example 10, wherein the optical path includes a waveguide in the glass core layer.

Example 12 includes the subject matter of Example 10 or 11, further comprising a connector to couple with a pluggable fiber array unit (FAU) and direct light from the FAU to the optical path.

Example 13 includes the subject matter of Example 10 or 11, further comprising v-grooves in the glass core to couple with optical fibers of a fiber array unit (FAU) and direct light from the optical fibers to the optical path.

Example 14 includes the subject matter of any one of Examples 10-13, wherein the optical path includes a microlens.

Example 15 includes the subject matter of any one of Examples 10-14, wherein the EIC is at least partially embedded in package substrate.

Example 16 includes the subject matter of any one of Examples 10-14, wherein the EIC is on the package substrate.

Example 17 includes the subject matter of Example 16, wherein the one or more build-up layers include at least one redistribution layer to electrically connect the processor and the EIC.

Example 18 includes the subject matter of Example 16, wherein the package substrate comprises bridge circuitry to electrically connect the processor and the EIC.

Example 19 is a system comprising: an integrated circuit package according to any one of Examples 10-18; and a fiber array unit (FAU) coupled to the integrated circuit package.

Example 20 includes the subject matter of Example 19, wherein the optical path includes a waveguide in the glass core layer and the FAU is a pluggable FAU comprising a male portion in optical alignment with the waveguide.

Example 21 includes the subject matter of Example 19, wherein the optical path includes a first microlens and the FAU comprises a second microlens in optical alignment with the first microlens.

Example 22 includes the subject matter of Example 19, wherein the glass core layer comprises a plurality of waveguides and a plurality of v-grooves, and the FAU comprises a plurality of fiber optic cables in respective v-grooves and in optical alignment with respective waveguides of the glass core layer.

Example 23 includes the subject matter of any one of Examples 19-22, wherein the EIC is at least partially embedded in package substrate.

Example 24 includes the subject matter of any one of Examples 19-22, wherein the EIC is on the package substrate.

Example 25 includes the subject matter of Example 24, wherein the one or more build-up layers include at least one redistribution layer to electrically connect the processor and the EIC.

Example 26 includes the subject matter of Example 24, wherein the substrate comprises bridge circuitry to electrically connect the processor and the EIC.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit device comprising:
a glass core layer;
one or more build-up layers on the glass core layer;
a photonics integrated circuit (PIC) at least partially within a cavity of the glass core layer; and
an optical path between the PIC and an end of the integrated circuit device.

2. The integrated circuit device of claim 1, wherein the optical path includes a waveguide formed in the glass core layer.

3. The integrated circuit device of claim 1, further comprising a connector to couple with a pluggable fiber array unit (FAU) and direct light from the FAU to the optical path.

4. The integrated circuit device of claim 1, further comprising v-grooves in the glass core to couple with optical fibers of a fiber array unit (FAU) and direct light from the optical fibers to the optical path.

5. The integrated circuit device of claim 1, wherein the optical path includes a microlens.

6. The integrated circuit device of claim 1, further comprising an electronic integrated circuit (EIC) in electrical connection with the PIC.

7. The integrated circuit device of claim 6, wherein the EIC is at least partially embedded in the one or more build-up layers.

8. The integrated circuit device of claim 6, wherein the EIC is on the build-up layers.

9. The integrated circuit device of claim 6, further comprising a processor in electrical connection with the EIC.

10. The integrated circuit device of claim 9, wherein the one or more build-up layers include at least one redistribution layer to electrically connect the processor and the EIC.

11. An integrated circuit package comprising:
a package substrate comprising a glass core layer;
an optical path at least partially in the glass core layer;
a photonics integrated circuit (PIC) at least partially embedded in the glass core layer and in optical connection with the optical path;
an electronic integrated circuit (EIC) in electrical connection with the PIC; and
a processor in electrical connection with the EIC.

12. The integrated circuit package of claim 11, wherein the optical path includes a waveguide in the glass core layer.

13. The integrated circuit package of claim 11, further comprising a connector to couple with a pluggable fiber array unit (FAU) and direct light from the FAU to the optical path.

14. The integrated circuit package of claim 11, further comprising v-grooves in the glass core to couple with optical fibers of a fiber array unit (FAU) and direct light from the optical fibers to the optical path.

15. The integrated circuit package of claim 11, wherein the optical path includes a microlens.

16. The integrated circuit package of claim 11, wherein the EIC is at least partially embedded in package substrate.

17. The integrated circuit package of claim 11, wherein the EIC is on the package substrate.

18. The integrated circuit package of claim 17, wherein the one or more build-up layers include at least one redistribution layer to electrically connect the processor and the EIC.

19. The integrated circuit package of claim 17, wherein the package substrate comprises bridge circuitry to electrically connect the processor and the EIC.

20. A system comprising:
an integrated circuit package comprising:
a substrate comprising a glass core layer;
an optical path at least partially in the glass core layer;
a photonics integrated circuit (PIC) at least partially embedded in the glass core layer and in optical connection with the optical path;
an electronic integrated circuit (EIC) in electrical connection with the PIC; and
a processor in electrical connection with the EIC; and
a fiber array unit (FAU) coupled to the integrated circuit package.

21. The system of claim 20, wherein the optical path includes a waveguide in the glass core layer and the FAU is a pluggable FAU comprising a male portion in optical alignment with the waveguide.

22. The system of claim 20, wherein the optical path includes a first microlens and the FAU comprises a second microlens in optical alignment with the first microlens.

23. The system of claim 20, wherein the glass core layer comprises a plurality of waveguides and a plurality of v-grooves, and the FAU comprises a plurality of fiber optic cables in respective v-grooves and in optical alignment with respective waveguides of the glass core layer.

24. The system of claim 20, wherein the EIC is at least partially embedded in package substrate.

25. The system of claim 20, wherein the EIC is on the package substrate.
